(19) United States
(12) Patent Application Publication
(10) Pub. No.: US 2012/0067410 A1
(43) Pub. Date: Mar. 22, 2012

(54) SCHOTTKY-BARRIER JUNCTION ELEMENT, AND PHOTOELECTRIC CONVERSION ELEMENT AND SOLAR CELL USING THE SAME

(75) Inventors: Nobuyuki Matsuki, Ibaraki (JP); Yoshihiro Irokawa, Ibaraki (JP); Kenji Itaka, Ibaraki (JP); Hideomi Koinuma, Ibaraki (JP); Masatomo Sumiya, Ibaraki (JP)

(73) Assignee: NATIONAL INSTITUTE FOR MATERIALS SCIENCE, Tsukuba-shi, Ibaraki (JP)

(21) Appl. No.: 13/258,205

(22) PCT Filed: Mar. 29, 2010
(86) PCT No.: PCT/JP2010/055574

§ 371 Date: Dec. 1, 2011

(30) Foreign Application Priority Data
Mar. 27, 2009 (JP) 2009-077948

(51) Int. Cl. H01L 31/07; H01L 29/161; H01L 29/47; H01L 29/20

(52) U.S. Cl. 136/255; 257/76; 257/77; 257/471; 257/E29.084; 257/E29.089; 257/E29.148

(57) ABSTRACT

A Schottky-barrier junction element 1 has a Schottky-barrier junction between an organic semiconductor 3 and an organic conductor 4. The inorganic semiconductor 3 is any one of nitride semiconductors, Si, GaAs, CdS, CdTe, CuInGaSe, InSb, PbTe, PbS, Ge, InN, GaSb, and SiC. A solar cell uses this Schottky-barrier junction element 1, with its photoelectric conversion section including the Schottky junction. A photoelectric conversion element uses this Schottky-barrier junction element 1, with its conversion section for interconverting light and electricity including the Schottky junction.

### TECHNICAL FIELD

The present invention relates to a Schottky-barrier junction element having a Schottky-barrier junction formed between an inorganic semiconductor and an organic conductor, and a photoelectric conversion element and a solar cell using the same.

### BACKGROUND ART

A Schottky-barrier junction between a metal and a semiconductor is known. This Schottky-barrier junction is used in Si integrated circuits in combination with bipolar transistors and field-effect transistors.

Non-patent Literature 1 discloses a Schottky-barrier photoelectric conversion element wherein a Schottky barrier is formed between an n-type semiconductor and a metallic thin film having work function of 5 eV or higher such as Au and Pd. With the conventional Schottky-barrier photoelectric conversion elements such as the one disclosed in Non-patent Literature 1, since significant attenuation of incident light occurs at metallic thin film electrodes, sufficient performance as a photoelectric conversion element cannot be ensured, which makes it difficult to put it into practical use.

Patent Literatures 1 and 2, and Non-patent Literatures 2, 3, and 4 disclose Schottky photoelectric conversion, elements forming a Schottky barrier with an organic conductor such as poly(3,4-ethylenedioxythiophene)poly(styrenesulfonate) (PEDOT:PSS) and nickel phthalocyanine, a metallic thin film such as Au and Pd, and an oxide semiconductor such as TiO₂ and SrTiO₃. Since the light transmittance of organic conductors such as PEDOT:PSS and nickel phthalocyanine is higher than that of metallic thin films, the problem of occurrence of significant attenuation of incident light can be avoided.

However, since Shottky-barrier photoelectric conversion elements use oxides having a large optical band gap such as TiO₂ and SrTiO₃ as semiconductors, the wavelength region allowing the elements to have sensitivity as photoelectric conversion elements has been limited to shorter than 380 nm. This obstructive factor has prevented the elements from being used as a solar cell, which requires spectral sensitivity to visible light falling within the 400 nm to 800 nm region.

### CITATION LIST

### Patent Literature

Patent Literature 1: JP2008-244006A
Patent Literature 2: JP2004-214547A
Non-patent Literature

Non-patent Literature 1: K. M. Tracy et al., J. Appl. Physics Vol. 94, p. 3939 (2003)
Non-patent Literature 2: J. Yamamura et al., Appl. Phys. Lett. Vol. 83, p. 2097 (2003)
Non-patent Literature 3: M. Nakano et al., Appl. Phys. Lett. Vol. 91, p. 142113 (2007)
Non-patent Literature 4: M. Nakano et al., Appl. Phys. Lett. Vol. 93, p. 123309 (2008)

### SUMMARY OF THE INVENTION

### Technical Problem

The present invention intends to provide a Schootky-barrier junction element having a high Schottkey barrier, and a photoelectric conversion element and a solar cell using the Schottky-barrier junction element.

### Solution to Problem

To achieve the above objectives, the Schottky-barrier junction element of the present invention has a Schottky junction between an inorganic semiconductor and an organic conductor, wherein the inorganic semiconductor is any one of the following: Nitride semiconductors, Si, GaAs, CdS, CdTe, CuInGaSe. InSb, PbTe, PbS, Ge, InN, GaSb, and SiC.

To achieve the above objectives, the solar cell according to the present invention uses the Schottky-barrier junction element of the present invention, wherein a photoelectric conversion section includes the Schottky-barrier junction.

To achieve the above objectives, the photoelectric conversion element of the present invention uses the Schottky-barrier junction element of the present invention, wherein a conversion section for interconverting light and electricity includes the Schottky -barrier junction.

### Advantageous Effects of the Invention

According to the present invention, by providing an organic conductor on a specific inorganic semiconductor, a Schottky-barrier junction element having a high Schottky barrier can be provided. In particular, since the organic conductor has high light transmittance, the use as a photoelectric conversion element and solar cell exhibits good performance. By selecting an inorganic semiconductor having a specific band gap, absorption wavelength can be shifted from ultraviolet light to visible light, which ensures effective use of photoelectric effect in the visible light range.

### BRIEF DESCRIPTION OF THE DRAWINGS

FIG. 1 is a schematic diagram of a Schottky-barrier junction element related to the embodiment of the present invention, namely a schematic structural drawing of a solar cell based on the junction between an organic conductor and a nitride semiconductor shown in Example 1.

FIG. 2 is a cross-sectional view of the solar cell shown in FIG. 1, illustrating its manufacturing process.

FIG. 3 is a linear plot showing dark current/voltage characteristics of the solar cell in Example 1.

FIG. 4 is a semilogarithmic plot showing dark current/voltage characteristics of the solar cell in Example 1.

FIG. 5 shows current/voltage characteristics of the solar cell in Example 1 obtained under conditions illuminated by a xenon lamp.

FIG. 6 presents the light transmittance measurement result of the organic conductor and the spectral sensitivity measurement result of the solar cell shown in Example 1.

FIG. 7 is a schematic diagram of a solar cell shown in Example 2 based on the junction of an oxide conductor, organic conductor, and a nitride semiconductor.

FIG. 8 is a cross-sectional view of the solar cell shown in Example 2 illustrating its manufacturing process.

FIG. 9 is a linear plot illustrating the dark current/voltage characteristics of the solar cell shown in Example 2.

FIG. 10 is a semilogarithmic plot illustrating the dark current/voltage characteristics of the solar cell shown in Example 2.

FIG. 11 shows the current/voltage characteristics of the solar cell shown in Example 2 obtained under the conditions where light was irradiated by a xenon lamp.

FIG. 12 is a schematic diagram of a measurement system for measuring current/voltage characteristics while irradiating light from a xenon lamp to the solar cell shown in Example 2.

### DESCRIPTION OF EMBODIMENTS

The embodiment of the present invention will hereinafter be described by referring to the drawings.

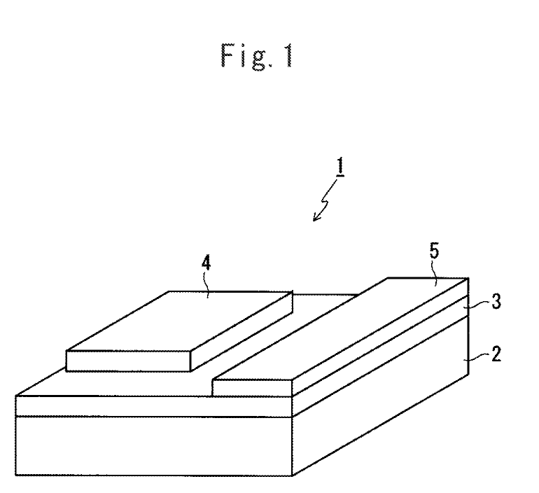

FIG. 1 is a schematic diagram of a Schottky-barrier junction element related to the embodiment of the present invention. The Schottky-barrier junction element 1 according to the embodiment of the present invention includes: a substrate 2; an inorganic semiconductor 3 provided on the substrate 2; an organic conductor 4 that is provided on the inorganic semiconductor 3 and that forms a Schottky barrier with the inorganic semiconductor 3; and an electrode 5 that is provided on the inorganic semiconductor 3 aligned with but separated from the organic conductor 4 and that forms an ohmic contact with the inorganic semiconductor 3.

As the substrate 2, a sapphire substrate, etc. may be used.

As the inorganic semiconductor 3, not only III-V semiconductors such as GaN, nitride semiconductors in particular, but also Si such as single-crystal Si, polycrystal Si, and amorphous Si, GaAs, CdS, CdTe, CuInGaSe, InSb, PbTe, PbS, Ge, InN, GaSb, and SiC can be used.

As the organic conductor 4, various polythiophene-series, polyaniline-series, polyacetylene-series, polyphenylene-series, and polypyrrole-series organic conductors can be used. Table 1 lists examples of organic conductors.

TABLE 1
List of various organic conductors usable for Schottky-barrier junction element

| | Chemical | | Structural | Product | Sales | Conduc- | Transmit- |
|---|---|---|---|---|---|---|---|
| | name | Abbreviation | formula | name | company | tivity | tance |
| Polythiophene series | Poly(3,4- ethylenedioxy thiophene)poly (styrenesulfonate) | PEDOT/PSS | 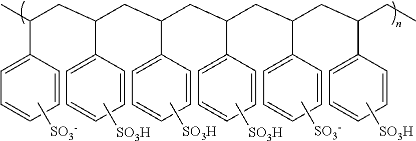 | PEDOT/PSS | Sigma- Ardrich | 1 × 10⁻⁵ ~ 1 S/cm | 90% @ 400 nm |
| | Poly(2,3-dihydro- thieno-1,4-dioxin)- poly(styrene- sulfonate) | | 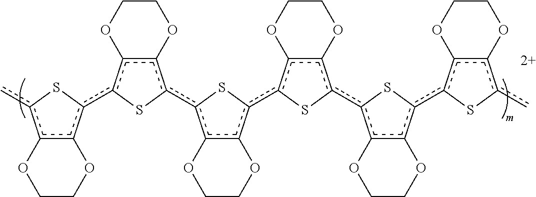 | CLEVIOS | H. C. Starck | <500 S/cm | — |
| | Poly(3,4-ethylene dioxythiophene)- block-poly(ethylene glycol) | PEDOT/PEG | 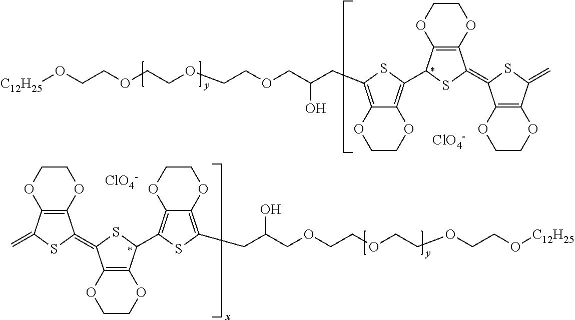 | Aedotron ™ Oligotron ™ | Sigma- Ardrich | 1 × 10⁻⁴ ~ 60 S/cm | 95% @ 400 nm |
| | Poly(thiophene-3- [2-(2-methoxy- ethoxy)ethoxy]- 2,5-diyl) | Plexcore, Sulfonated polythiophene ink | 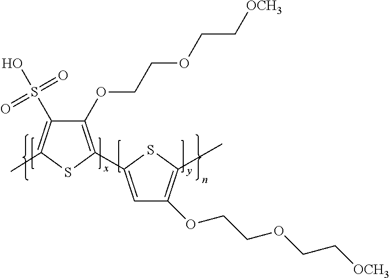 | Plexcore | Sigma- Ardrich | 1 × 10⁻² − 1 × 10⁻⁵ S/cm | — |
| Polyaniline series | Polyaniline (emeraldine salt) | Emeraldine base polyaniline, PAN1 | 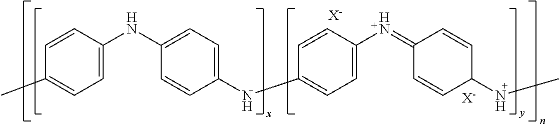 | Polyaniline | Sigma- Ardrich | <20 S/cm | — |
| Polyacetylene series | Poly[1,2-bis (ethylthio) acetylene] | Bis(ethylthio) acetylene polymer | 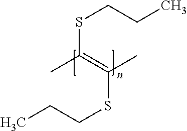 | Bis(ethylthio) acetylene polymer | Sigma- Ardrich | — | — |
| Ployphenylene series | Poly(1,4-phenylene sulfide) | | 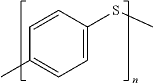 | Poly(1,4- phenylene sulfide) | Sigma- Ardrich | — | — |
| Polypyrrol series | Polypyrrole | | 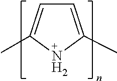 | Polypyrrole | Sigma- Ardrich | 10-40 S/cm | — |

As polythiophene-series organic conductors, poly(3,4-ethylenedioxythiophene)poly(styrenesulfonate) expressed by chemical formula (1), poly(3,4-ethylenedioxythiophene)-block-poly (ethylene glycol) expressed by chemical formula (2), poly(thiophene-3-[2-(2-methoxyethoxy)ethoxy]-2,5-diyl) expressed by chemical formula (3), etc. can be used.

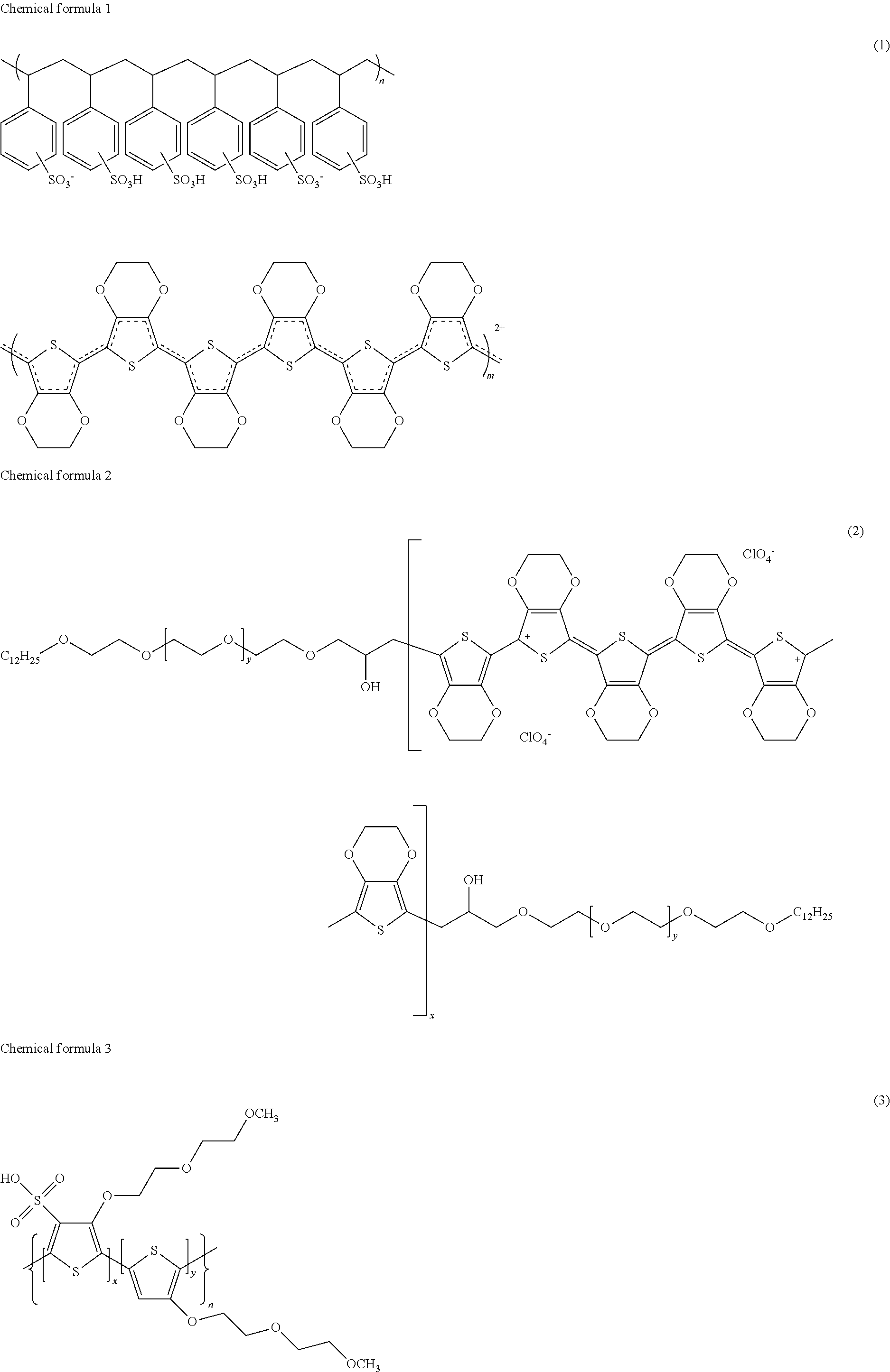

As polyaniline-series organic conductors, polyaniline expressed by chemical formula (4) can be used, for example.

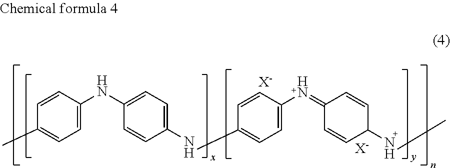

As polyacetylene-series organic conductors, poly[1,2-bis(ethylthio)acetylene] expressed by chemical formula (5) can be used, for example.

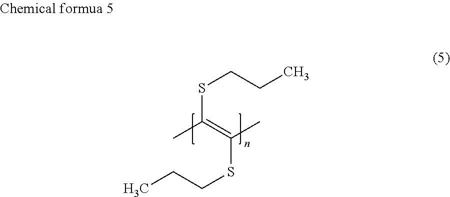

As polyphenylene-series organic conductors, poly(1,4-phenylene sulfide) expressed by chemical formula (6) can be used.

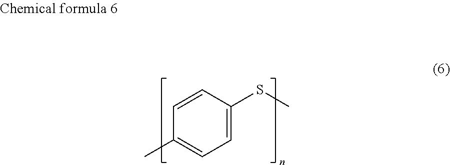

As polypyrrole-series organic conductors, polypyrrole expressed by chemical formula (7) may be used, for example.

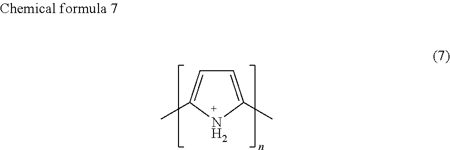

In the embodiment of the present invention, a Schottky-barrier junction is formed between the inorganic semiconductor 3 and the organic conductor 4. If the inorganic semiconductor 3 is an n-type semiconductor, a hole-conduction-type organic conductor 4 can be used to form a Schottky-barrier junction. In this case, an inorganic semiconductor 3 having the electron affinity of less than 5.0 eV must be used. Theoretically, if the electron affinity of the inorganic semiconductor 3 is smaller than the work function of p-type organic semiconductor, a Schottky barrier can be formed. In practice, however, Schottky characteristics cannot be obtained unless there is a difference of approximately 1 eV. It is therefore preferable that the electron affinity of the organic semiconductor 3 be smaller than the work function of the p-type organic semiconductor by 1 eV or more. In Examples 1 to 3 to be described below, the work function of the organic conductor 4 is approximately 5 eV, and the electron affinity of the inorganic semiconductor 3 is approximately 3.5±0.3 eV. Since the difference between the work function of the organic conductor 4 and the electron affinity of the inorganic semiconductor 3 is higher than 1 eV, a good Schottky junction can be achieved.

The embodiment of the present invention is the Schottky-barrier junction element 1. However, the embodiment can be applied to various photoelectric conversion elements such as ultraviolet sensor, infrared sensor, solar cell, diode element for voltage control, and variable-capacity diode element.

Namely, the solar cell in the embodiment of the present invention uses the Schottky-barrier junction element 1, and the conversion section for converting light into electricity includes a Schottky-barrier junction.

The photoelectric conversion element in the embodiment of the present invention uses the Schottky-barrier junction element 1, and the conversion section for converting light into electricity, or vice versa, includes a Schottky-barrier junction.

In the embodiment of the present invention to be described below, highly-conductive polyaniline-series organic solvent solution (ORMECON) was used as the organic conductor 4, and gallium nitride was used as the nitride semiconductor. As the highly-conductive polyaniline-series organic solvent solution, the one containing water as solvent and having viscosity of 16 mPa·s, ph of 1.8, and the conductivity found by spin-coating deposition of 180 S/cm under the measurement environment of 25° C. was used. However, it is easy to imagine that similar Schottky-barrier junctions can be achieved by using other hole conduction-type organic materials such as PEDOT:PSS as the organic conductor 4, and various inorganic semiconductors such as Si including single-crystal Si, polycrystal Si, and amorphous Si, GaAs CdS, CdTe, and CuInGaSe as the inorganic semiconductor 3. The work function of ORMECON and that of PEDOT:PSS are both assumed to be 5.0 eV. Inorganic n-type semiconductors capable of forming a Schottky-barrier junction with these materials are those whose electron affinity is less than 5.0 eV. Namely, the electron affinity of CdS, CdTe, GaAs, Si, and CuInGaSe is 4.8 eV, 4.3 eV, 4.07 eV, 4.05 eV, and 4.0 eV respectively, it is easy to imagine based on general knowledge on semiconductor physics that the use of these n-type inorganic semiconductors forms a Schottky-barrier junction.

### EXAMPLE 1

A solar cell having the same structure as the one shown in FIG. 1 was made. The solar cell will be described by referring to FIG. 1. The solar cell 1 of this example includes a sapphire substrate 2, a GaN film 3 provided on the substrate, and an organic conductor (ORMECON) 4 and an indium electrode 5 aligned on the GaN film 3.

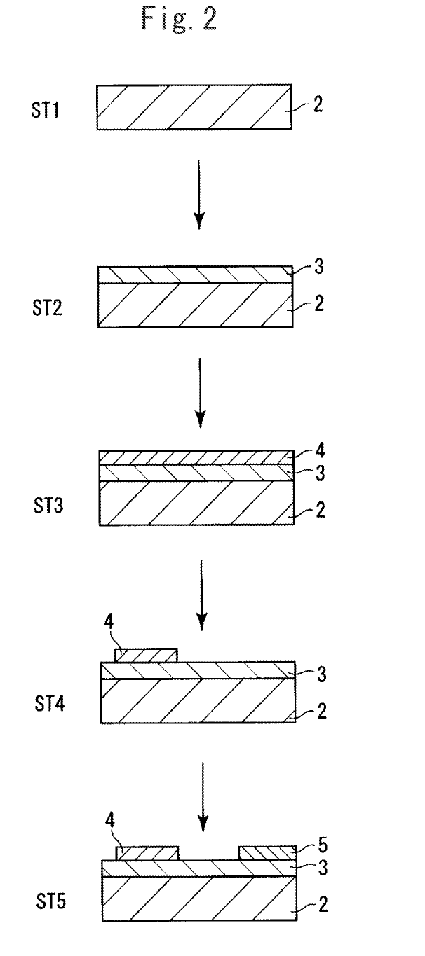

FIG. 2 shows the flow of manufacturing the solar cell shown in FIG. 1.

In step ST1, a sapphire (0001) substrate 2 was prepared. In step ST2, using trimethyl gallium, ammonia, and hydrogen as raw materials, epitaxial growth of gallium nitride (GaN) was promoted by the organic metal vapor phase growth method until a thickness of 3 μm was obtained to form a GaN film 3 on the sapphire (0001) substrate 2. In Example 1, a commercially available sapphire substrate 2 having a GaN film 3 on its surface was used. This sapphire substrate 2 was n-GaN epitaxial wafer (wafer No. PT01AB04H26491121) (POWDEC K.K.) with an undoped layer having the thickness of 1 μm and a doped layer having the thickness of 2 μm laminated on the sapphire substrate (0001) in that order, and with the total film thickness measuring 3 μm.

In step ST3, coating of the organic conductor 4 by spin coating and baking were conducted. As spin coating, 2 mL of a stock solution of organic conductor (p-type conductive polymeric polyaniline, ORMECON) was applied to the GaN film 3 evenly using a pipet, revolution was accelerated to 1000 rpm in 10 seconds, 1000 rpm was maintained for 10 seconds, revolution was further accelerated to 4000 rpm in another 10 seconds, 4000 rpm was maintained for 30 minutes, and then decelerated to 0 rpm in 10 seconds. Regarding the above operations as one set, four sets were repeated. The spin-coated item was then left on a hot plate heated to the temperature setting of 150° C. for 10 minutes for drying/baking. The above operations were all conducted in the atmosphere. After baking, film thickness of the organic conductor 4 was measured by a surface profiler, and the average of film thickness was found to be 173 nm.

In step ST4, unnecessary parts of the organic conductor 4 were peeled off. Namely, the organic conductor 4 covering the GaN film 3 evenly was peeled using a pair of stainless steel tweezers, exposing the surface of the GaN film 3, except for the area of the element of 2.7 mm×3.1 mm.

In step ST5, an indium electrode 5 was formed. Namely, on a part of the surface of the GaN film 3 exposed in ST4, indium metal was soldered to make the indium electrode 5 in ohmic contact with the GaN film 3.

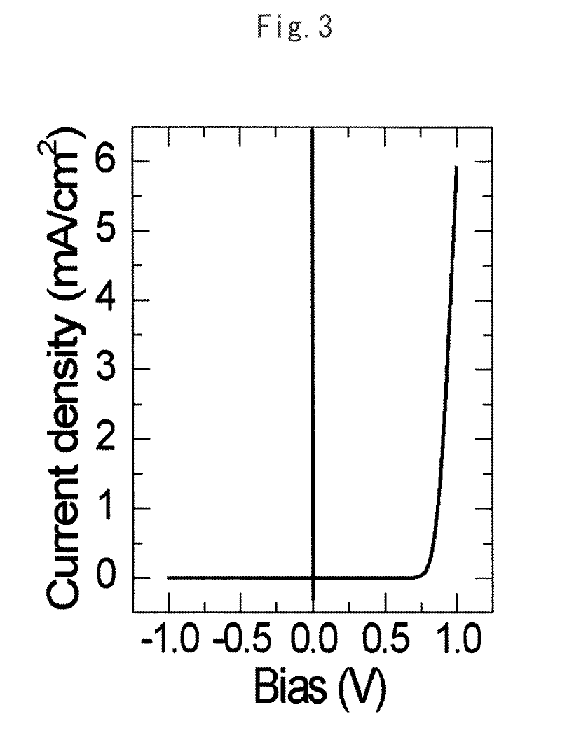

FIG. 3 is a chart showing the current density/voltage characteristics found from the result of current/voltage measurement of solar cell 1. The area of the element of the solar cell 1 was 0.0837 cm². The calculated current density/voltage characteristics show that the solar cell 1 exhibited rectifying property, indicating that a Schyottky barrier was formed with the organic conductor 4 and the GaN film 3.

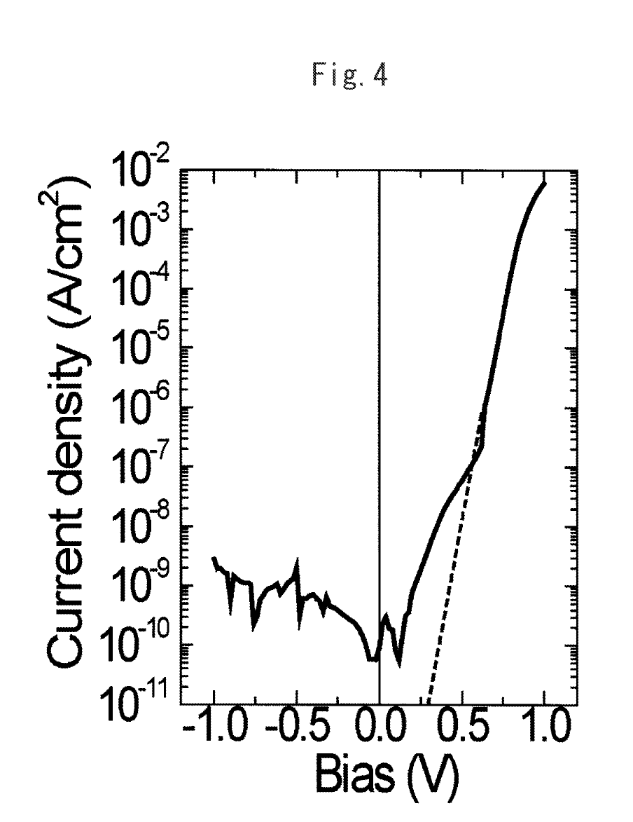

FIG. 4 is a semilogarithmic plot showing the current density/voltage characteristics in FIG. 3. From a linear y section fitted to the linear region of the semilogarithmic plot, ideal diode value n and saturated current density J₀ are calculated. In addition, from this J₀, the Schottky barrier height f_{B} can be calculated. The results of the fitting were as follows: n=1.2, f_{B}=1.25 eV.

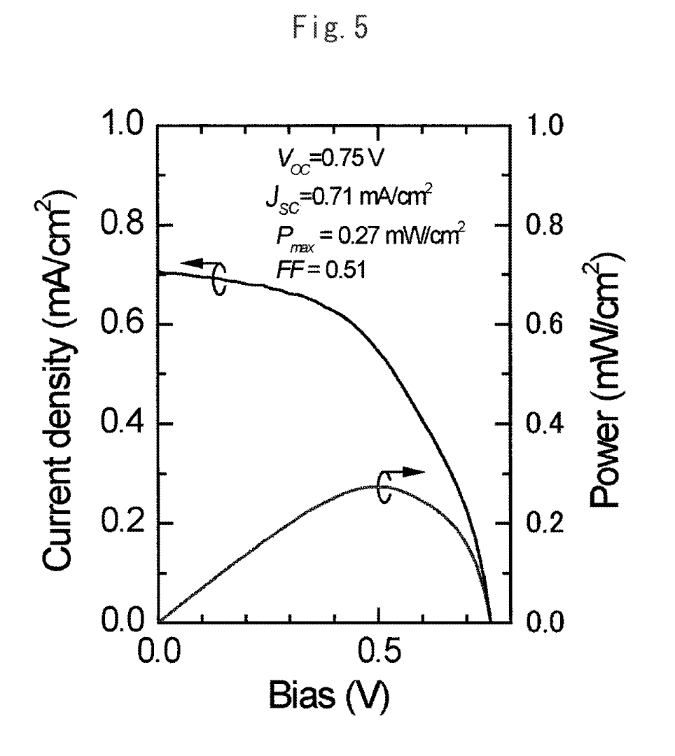

FIG. 5 shows current/voltage characteristics obtained based on the results of current/voltage measurement conducted while light was irradiated from a xenon lamp to the solar cell in Example 1. The area of the element of the solar cell 1 was 0.0837 cm². To make the effect of photoelectric conversion more visible, the positive and negative current values were reversed, with a part enlarged. The voltage at an open end V_{OC}, short-circuit current density J_{SC}, maximum output Pₘₐₓ, and fill factor FF were 0.75 V, 0.71 mA/cm², 0.27 mW/cm², and 0.51 respectively.

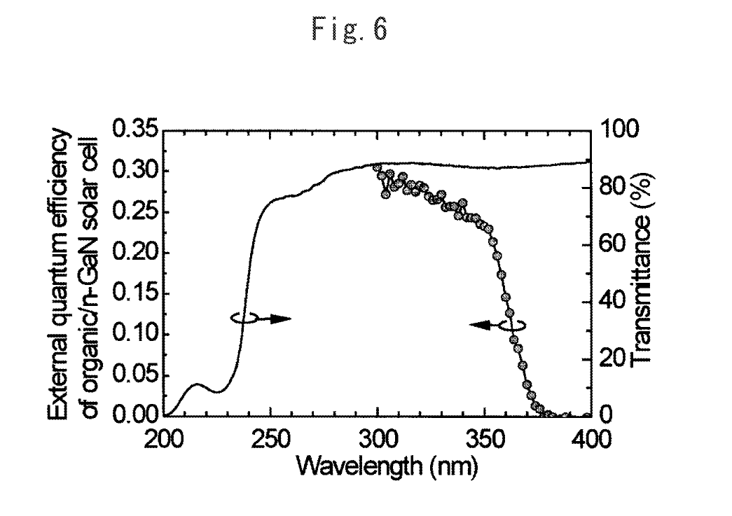

FIG. 6 is a chart illustrating the measurement results of light transmittance of the organic conductor 4 and the spectral sensitivity of the solar cell 1. By applying ORMECON to a 0.4-mm-thick crystal substrate in thickness of 173 nm using the method shown in step ST3, and by performing baking, a sample was made, and measurement was conducted using this sample.

It was found by the light transmittance measurement of the organic conductor 4 that the organic conductor 4 had the light transmittance of 75% to 85% in the wavelength region from 250 nm to 280 nm, and approximately 90% in the wavelength region of 280 nm and longer.

As shown by the measurement result of the spectral sensitivity of the solar cell 1, the spectral sensitivity increased sharply in the short wavelength side centered around 360 nm, which is the wavelength of optical band edge of GaN, and external quantum efficiency of organic/n-GaN solar cell reached 0.3 at 300 nm.

### EXAMPLE 2

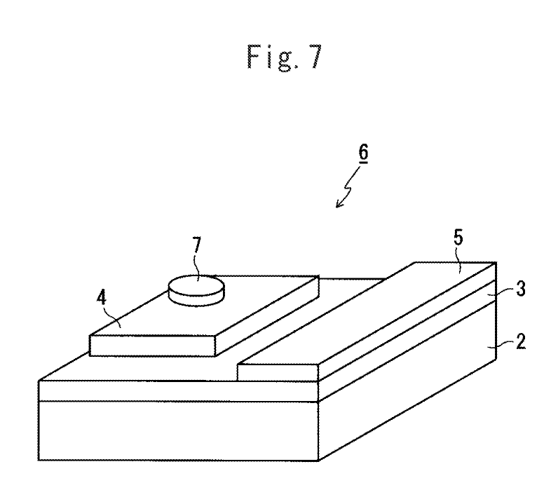

FIG. 7 is a perspective view illustrating the structure of a solar cell 6 related to Example 2. The solar cell 6 is structured with a transparent conductive oxide 7, organic conductor 4, and inorganic semiconductor 3 interfaced together. The solar cell 6 includes: a sapphire substrate 2; a GaN film as an inorganic semiconductor 3 provided on the sapphire substrate 2; ORMECON (highly-conductive polyaniline-series organic solvent solution) as the organic conductor 4 and an indium electrode 5 aligned on the inorganic semiconductor 3; and a transparent conductive oxide 7 provided on the surface of the organic conductor 4.

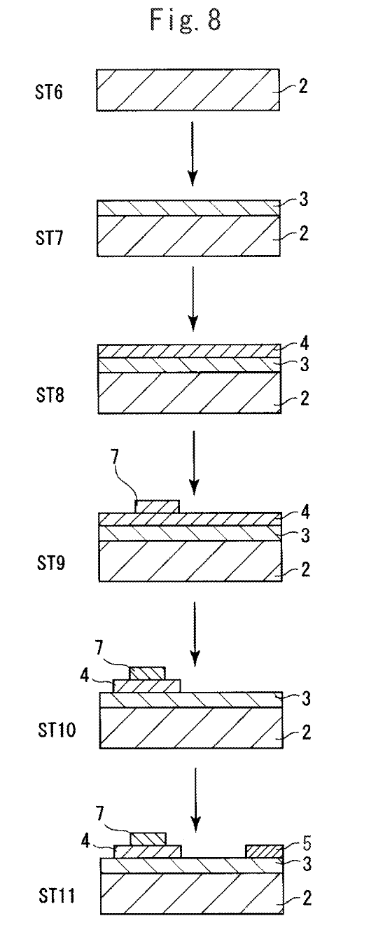

FIG. 8 illustrates the manufacturing process of the solar cell 6 shown in FIG. 7.

In step ST6, a sapphire substrate 2 was provided, in step 7, a GaN film was formed on the sapphire substrate 2 as the inorganic semiconductor 3, and in step 8, an organic conductor 4 was formed on the GaN film as the inorganic semiconductor 3, all of which are the same as steps ST1, ST2, and ST3 in Example 1. Detailed description is therefore omitted.

In step ST9, tin-doped indium oxide was deposited as the transparent conductive oxide 7 by the magnetron sputtering method. Sputtering deposition was conducted in a state where a stainless steel mask having an opening of 0.75 mm in diameter was adhered to the sample obtained in step ST8 to obtain a circular deposition area of 0.75 mm in diameter. The sputtering conditions were as follows: Target material; tin-doped indium oxide, argon flow rate; 19.2 sccm, oxygen flow rate; 0.8 sccm, and radiofrequency power; 200 W. The reaction pressure at that time was 0.29 Pa. After the deposition, film thickness of the transparent conductive oxide 7 was measured by a surface profiler, and the average of film thickness was found to be 124 nm.

In step ST10, unnecessary area of the organic conductor 4 was peeled off. Namely, the organic conductor 4 covering the GaN film 3 evenly was peeled off using a pair of stainless steel tweezers to expose the surface of the GaN film 3 except a rectangular area of 1.6 mm×2.0 mm.

In step ST11, an indium electrode 5 was formed. Namely, on a part of the surface of the GaN film 3 exposed in step ST10, indium metal was soldered to create the indium electrode 5 in ohmic contact with the GaN film 3.

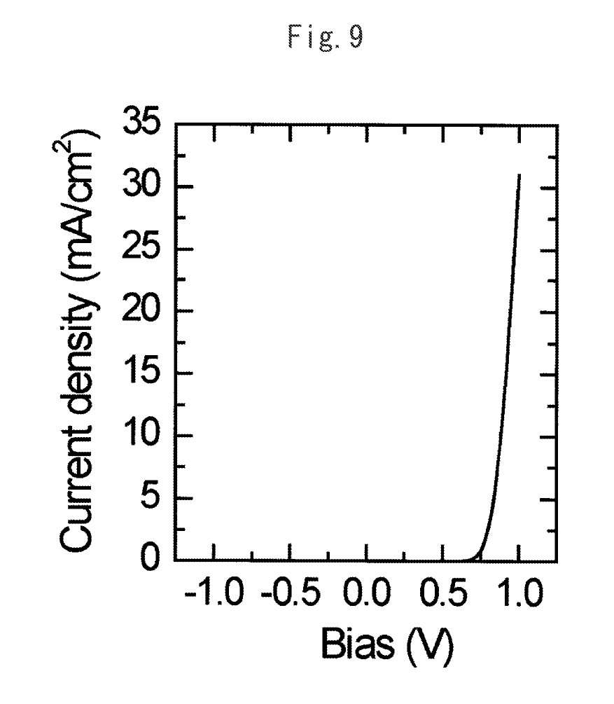

FIG. 9 is a linear plot illustrating the dark current/voltage characteristics of the solar cell 6 manufactured in Examples 2. Based on the results of current/voltage measurement of the solar cell 6, the current density/voltage characteristics were calculated. The area of the element of the solar cell 6 was 0.032 cm². From the linear plot showing the current density/voltage characteristics, it was found that the solar cell 6 exhibited rectifying property, and that a Schottky barrier had been formed with the organic conductor 4 and the GaN film 3. In addition, by depositing the transparent conductive oxide 7 by magnetron sputtering deposition, good interface was made between the organic conductor 4 and the GaN film 3 without damaging the organic conductor 4, which is the base.

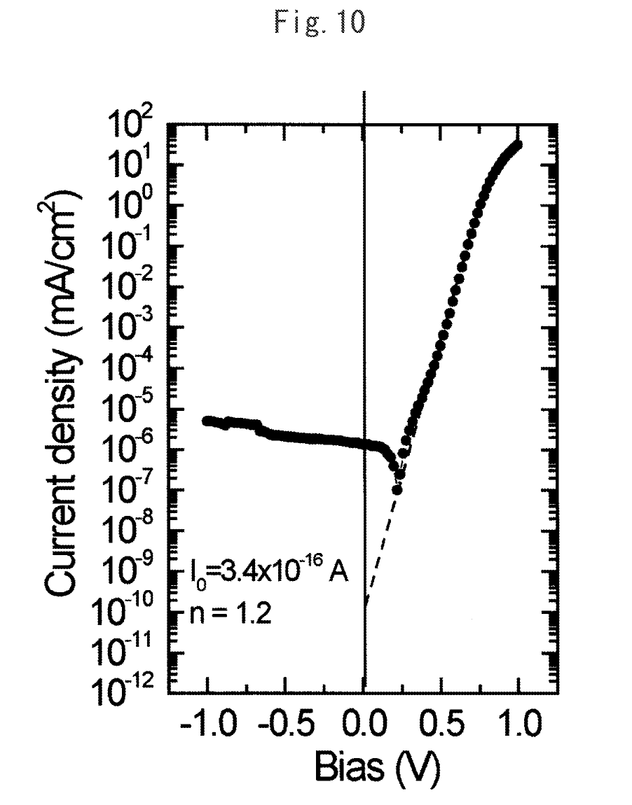

FIG. 10 is a semilogarithmic plot illustrating the dark current/voltage characteristics of the solar cell 6. From a linear y section fitted to the linear region of the semilogarithmic plot, ideal diode value n and saturated current density J₀ were calculated. In addition, from this J₀, the Schottky barrier height f_{B} was calculated. The results of the fitting were as follows: n=1.2, f_{B}=1.2 eV.

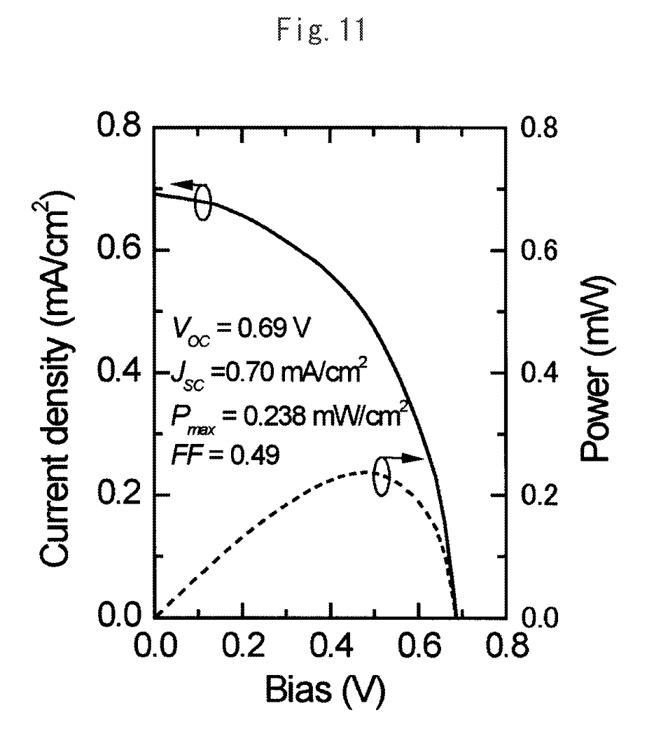

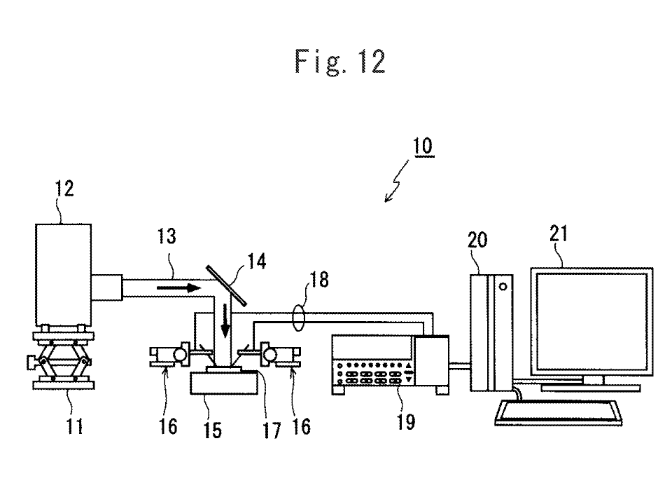

FIG. 11 is a chart illustrating the current/voltage characteristics of the solar cell 6 obtained while light was irradiated from a xenon lamp. FIG. 12 is a schematic diagram of a measurement system 10 used to measure the current/voltage characteristics of the solar cell while the light was irradiated from the xenon lamp. With the measurement system 10, a xenon lamp light source 12 is placed on a xenon lamp light source supporting and raising/lowering mechanism 11 to irradiate the light 13 of the xenon lamp. The light 13 of the xenon lamp irradiated from the xenon lamp light source 12 changes direction via a reflector 14 (such as aluminum deposited thin film reflector). and is irradiated to a sample (photoelectric conversion element) placed on a sample holder 15. The probes of a probe position adjusting mechanism 16 contact the electrodes of the sample 17 on the sample holder 15, and the probes are connected to the voltage and current measuring equipment 19 via wires 18. The voltage and current measuring equipment 19 is connected to a computer for data processing 20, which controls the voltage and current measuring equipment 19 and measures the current flow between the electrodes while changing the voltage to be applied between the electrodes by programs. The data obtained by the voltage and current measuring equipment 19 is stored in the computer for data processing 20 and displayed on a display 21.

Voltage and current were measured while the light 13 of the xenon lamp was irradiated from above the solar cell 6, and current density/voltage characteristics were calculated. The area of the element of the solar cell 6 was 0.032 cm². To make the effect of photoelectric conversion more visible, the positive and negative current values were reversed, with a part enlarged. The, voltage at an open end V_{OC}, short-circuit current density J_{SC}, maximum output density Pₘₐₓ, and fill factor FF were 0.69 V, 0.70 mA/cm², 0.238 mW/cm², and 0.49 respectively.

### EXAMPLE 3

As Example 3, an element was made following the same procedure as Example 1, with a non-doped GaN film having the thickness of 1 μm used as the inorganic semiconductor 3, PEDOT:PSS having the thickness of 10 μm as the organic conductor 4, and an Ag film having the thickness of 100 μm as the electrodes 5.

Similar to Example 1, the current/voltage characteristics were measured to calculate the current density/voltage characteristics. With the element manufactured in Example 3, the ideal diode value n was 1.8, ideal saturated current density J₀ was 6.5×10⁻¹² A, and the Schottky barrier height f_{B} was 1.8 eV.

Similar to Example 1, current/voltage measurement was conducted while the light of the xenon lamp was irradiated, and the voltage at open end V_{OC}, short-circuit current Isc, maximum output Pₘₐₓ, and fill factor FF were found to be 0.44 V, 3.84 nA, 0.64 nW, and 0.38 respectively.

Table 2 summarizes the results of Example 1 to Example 3.

TABLE 2

| | | Example 1 | | Example 2 | | Example 3 | |
|---|---|---|---|---|---|---|---|
| Substrate (2) | Material | SA | | SA | | SA | |
| | Thickness (mm) | 0.5 | | 0.5 | | 0.5 | |
| Inorganic | Material | n-type GaN | | n-type GaN | | non-doped GaN | |
| semiconductor (3) | Dopant | Si | | Si | | — | |
| | Doping (cm⁻³) | 6.3 × 10¹⁷ | | 6.3 × 10¹⁷ | | — | |
| | Thickness (μm) | 3 | | 3 | | 1 | |
| Organic conductor (4) | Material | OR | | OR | | PEDOT: PSS | |
| | Thickness (mm) | 173 | | 173 | | 10 | μm |
| Light transmittance | 250 to 280 nm | 75% to 85% | | 75% to 85% | | — | |
| | 280 to 400 nm | 90% | | 90% | | — | |
| | Visible light | 90% | | 90% | | — | |
| Electrode (5) | Material | In | | In | | Ag | |
| | Thickness (μm) | 30 | μm | 30 | μm | 100 | μm |
| Transparent conductive | Material | — | | ITO | | — | |
| oxide (7) | Thickness (μm) | — | | 124 | | — | |
| Ideal diode value | n | 1.2 | | 12 | | 1.8 | |
| Saturated current value | J₀(A) | 7.6 × 10⁻¹⁶ | | 3.4 × 10⁻¹⁶ | | 6.5 × 10⁻¹² | |
| Schottky barrier height | ØB(eV) | 1.25 | | 1.2 | | 1.8 | |
| Voltage value at open | Voc(V) | 0.75 | | 0.69 | | 0.44 | |
| Short-circuit current | Isc, Jsc | 0.71 | mA/cm² | 0.69 | mA/cm² | 3.84 | nA |
| density or short-circuit | | | | | | | |
| Maximum output power | Pmax | 0.27 | mW/cm² | 0.24 | mW/cm² | 0.6 | nW |
| density of maximum | | | | | | | |
| output power value | | | | | | | |

| | | | | |
|---|---|---|---|---|
| Fill factor | FF | 0.51 | 0.5 | 0.38 |
| Spectral sensitivity | 300 nm | 0.3 | — | — |

A Schottky-barrier junction element formed by the junction between the polythiophene-series organic conductor 4 and the GaN film 3 was shown in Examples 1 and 2, and a Schottkey-barrier junction element formed by the junction between polyaniline-series organic conductor and the GaN film was shown in Example 3, using the solar cell as a model. Organic conductors in the embodiments of the present invention are not limited to polythiophene-series or polyaniline-series organic conductors, but various organic conductors such as those shown in Table 1 may be used. Inorganic semiconductors are not limited to GaN, but various inorganic semiconductors shown in Table 3 can be used. Consequently, as shown in Table 4, Schottky-barrier junction elements can be achieved by the combination of any one of the organic materials A to E and any one of semiconductor materials.

TABLE 3
Band gap of various semiconductor materials

| | Semiconductor material | | | | | | | | | | | | |
|---|---|---|---|---|---|---|---|---|---|---|---|---|---|
| | 1: | 2: | 3: | 4: | 5: | 6: | 7: | 8: | 9: | 10: | 11: | 12: | 13: |
| | InSb | PbTe | PbS | Ge | InN | GaSb | CdS | CdTe | GaAs | Si | CuInGaSe | SiC | GaN |
| Band gap (eV), | 0.17 | 0.31 | 0.41 | 0.66 | 0.7 | 0.72 | 2.4 | 1.44 | 1.4 | 1.1 | — | 3.26 | — |
| Bulk crystal | | | | | | | | | | | | | |
| Band gap (eV), | — | — | — | — | — | — | — | — | — | 1.6 | 1.5 | — | — |
| Thin film | | | | | | | | | | | | | |

TABLE 4
Typical combinations of organic materials and semiconductor materials for Schottky-barrier junction element

| | Semiconductor material | | | | | | | | | | | | |
|---|---|---|---|---|---|---|---|---|---|---|---|---|---|
| Organic | 1: | 2: | 3: | 4: | 5: | 6: | 7: | 8: | 9: | 10: | 11: | 12: | 13: |
| material | InSb | PbTe | PbS | Ge | InN | GaSb | CdS | CdTe | GaAs | Si | CuInGaSe | SiC | GaN |
| A: Polythiophene | A-1 | A-2 | A-3 | A-4 | A-5 | A-6 | A-7 | A-8 | A-9 | A-10 | A-11 | A-12 | A-13 |
| series | | | | | | | | | | | | | |
| B: Polyaniline | B-1 | B-2 | B-3 | B-4 | B-5 | B-6 | B-7 | B-8 | B-9 | B-10 | B-11 | B-12 | B-13 |
| series | | | | | | | | | | | | | |
| C: Polyacetylene | C-1 | C-2 | C-3 | C-4 | C-5 | C-6 | C-7 | C-8 | C-9 | C-10 | C-11 | C-12 | C-13 |
| series | | | | | | | | | | | | | |
| D: Ployphenylene | D-1 | D-2 | D-3 | D-4 | D-5 | D-6 | D-7 | D-8 | D-9 | D-10 | D-11 | D-12 | D-13 |
| series | | | | | | | | | | | | | |
| E: Polypyrrol | E-1 | E-2 | E-3 | E-4 | E-5 | E-6 | E-7 | E-8 | E-9 | E-10 | E-11 | E-12 | E-13 |
| series | | | | | | | | | | | | | |

With the embodiment of the present invention, as described in Examples, a conductive polymeric coat was applied to the GaN film used as the inorganic semiconductor 3 to form a high Schottky barrier exceeding 1.2 eV between the inorganic semiconductor 3 and the organic conductor 4. This Schottky-barrier junction formed between the inorganic semiconductor 3 and the organic conductor 4 has high light transmittance. Consequently, if this Schottky-barrier junction is used for photoelectric conversion elements or a photoelectric conversion unit of a solar cell, good performance will be produced.

In addition, by controlling the band gap of the inorganic semiconductor 3, the absorption wavelength can be shifted from ultraviolet light to visible light, which allows photoelectric effect in the visible light range to be used. For example, if In is mixed with GaN as crystal to have InₓGa_{1-X}N, the band gap decreases, and when x is made to be equal to 1 eventually, the band gap becomes 0.7 eV. By changing compositions as described above, the band gap can be continuously controlled between 3.4 eV to 0.7 eV.

With the embodiment of the present invention, as shown in Examples 1 to 3, a device can be manufactured by an extremely simple method without using processes such as photolithography and dry etching.

Since devices can be configured using electrode materials easily available compared to rare and noble metals such as Au and Pd conventionally considered to be essential to form a Schottky barrier, high serviceability is ensured.

### INDUSTRIAL APPLICABILITY

In addition to the use as a solar cell, the photoelectric conversion element of the present invention can be used for the following devices.

The first application is an ultraviolet (intensity) sensor. Namely, the photoelectric conversion element can be used as a sensor for outputting current, without applying bias, in proportion to the intensity of ultraviolet light, thus measuring the intensity of ultraviolet light in the environment. Possible applications include an outdoor sunburn watch detector and a sensor used with a UV bactericidal lamp for checking that the amount of environmental UV light falls within the proper range.

The second application is an infrared ray sensor. By using a semiconductor having a small band gap, application as an infrared ray sensor is made possible. As such semiconductors, InSb, PbTe, PbS, Ge, InN, and GaSb are available. The band gap of InSb, PbTe, PbS, Ge, InN, and GaSb is 0.17 eV, 0.31 eV, 0.41 eV, 0.66 eV, 0.7 eV, and 0.72 eV respectively. Since they all have a small band gap, they are ideal fore an infrared ray sensor, and possible applications include a radiation thermometer and a human presence sensor.

The third application is a diode having various startup voltages. The Schottky-barrier height varies depending on the electron affinity of a semiconductor to be used. By selecting semiconductor materials having different electron affinities, the startup voltage of diodes can be changed, which is effective when using diodes for voltage control.

The fourth application is a variable-capacity diode. Since the width of a depletion layer changes in response to the application of voltage in reverse direction as with conventional diodes, the use as a variable-capacity diode is possible.

### Reference Sign List

1, 6: Solar cell (Schottky-barrier junction element)
2: Substrate
3: Inorganic semiconductor (GaN film)
4: Organic conductor
5: Electrode (indium electrode)
7: Transparent conductive oxide
10: Measurement system
11: Xenon lamp light source supporting and raising/lowering mechanism
12: Xenon lamp light source
13: Xenon lamp light
14: Reflector
15: Sample holder
16: Probe position adjusting mechanism
17: Sample
18: Wire
19: Voltage and current measuring equipment
20: Computer for data processing
21: Display

1. A Schottky-barrier junction element having a Schottky-barrier junction between an inorganic semiconductor and an organic conductor,
wherein the inorganic semiconductor is any one of nitride semiconductors, Si, GaAs, CdS, CdTe, CuInGaSe, InSb, PbTe, PbS, Ge, InN, GaSb, and SiC.

2. The Schottky-barrier junction element as set forth in claim 1,
wherein the nitride semiconductor is GaN.

3. The Schottky-barrier junction element as set forth in claim 1,
wherein the organic conductor is any one of polythiophene-series, polyaniline-series, polyacetylene-series, polyphenylene-series, and polypyrrole-series organic conductors.

4. A solar cell using the Schottky-barrier junction elements as set forth in claim 1,
wherein a conversion unit for converting light into electricity includes the Schottky junction.

5. A photoelectric conversion element using the Schottky-barrier junction elements as set forth in claim 1, wherein a conversion unit for interconverting light and electricity includes the Schottky junction.
